(19) United States
(12) Patent Application Publication
(10) Pub. No.: US 2024/0087882 A1
(43) Pub. Date: Mar. 14, 2024

(54) FLUORINE-DOPED SILICON-CONTAINING MATERIALS

(71) Applicant: Applied Materials, Inc., Santa Clara, CA (US)

(72) Inventors: Siyu Zhu, San Jose, CA (US); Hang Yu, San Jose, CA (US); Deenesh Padhi, Sunnyvale, CA (US); Sung-Kwan Kang, San Jose, CA (US); Abdul Wahab Mohammed, Sunnyvale, CA (US); Abhijit Basu Mallick, Fremont, CA (US)

(73) Assignee: Applied Materials, Inc., Santa Clara, CA (US)

(21) Appl. No.: 17/941,347

(22) Filed: Sep. 9, 2022

(51) Int. Cl. H01L 21/02; C23C 16/34; C23C 16/50; C23C 16/56; H01J 37/32

(52) U.S. Cl. CPC H01L 21/0217; C23C 16/342; C23C 16/345; C23C 16/50; C23C 16/56; H01J 37/32724; H01J 37/32844; H01L 21/02274; H01L 21/0228

(57) ABSTRACT

Exemplary semiconductor processing methods may include providing one or more deposition precursors to a processing region of a semiconductor processing chamber. The methods may include contacting a substrate housed in the processing region with the one or more deposition precursors. The methods may include forming a silicon-containing material on the substrate. The methods may include providing a fluorine-containing precursor to the processing region of the semiconductor processing chamber. The methods may include contacting the silicon-containing material on the substrate with the fluorine-containing precursor to form a fluorine-treated silicon-containing material. The methods may include contacting the fluorine-treated silicon-containing material with plasma effluents of argon or diatomic nitrogen.

### TECHNICAL FIELD

The present technology relates to deposition processes and chambers. More specifically, the present technology relates to methods of producing fluorine-doped silicon-containing materials.

### BACKGROUND

Integrated circuits are made possible by processes which produce intricately patterned material layers on substrate surfaces. Producing patterned material on a substrate requires controlled methods for forming and removing material. Material characteristics may affect how the device operates, and may also affect how the films are removed relative to one another. Plasma-enhanced deposition may produce films having certain characteristics. Many films that are formed require additional processing to adjust or enhance the material characteristics of the film in order to provide suitable properties.

Thus, there is a need for improved systems and methods that can be used to produce high quality devices and structures. These and other needs are addressed by the present technology.

### SUMMARY

Exemplary semiconductor processing methods may include providing one or more deposition precursors to a processing region of a semiconductor processing chamber. The methods may include contacting a substrate housed in the processing region with the one or more deposition precursors. The methods may include forming a silicon-containing material on the substrate. The methods may include providing a fluorine-containing precursor to the processing region of the semiconductor processing chamber. The methods may include contacting the silicon-containing material on the substrate with the fluorine-containing precursor to form a fluorine-treated silicon-containing material. The methods may include contacting the fluorine-treated silicon-containing material with plasma effluents of argon or diatomic nitrogen.

In some embodiments, the one or more deposition precursors include a silicon-containing precursor and a boron-containing precursor. A pressure within the semiconductor processing chamber may be maintained at less than or about 550° C. during the semiconductor processing method. The substrate may include a feature characterized by an aspect ratio of greater than or about 3:1. The methods may include, subsequent to forming the silicon-containing material on the substrate, halting a flow of the one or more deposition precursors. The methods may include reducing a pressure within the semiconductor processing chamber prior to providing the fluorine-containing precursor to the processing region of the semiconductor processing chamber. The pressure within the semiconductor processing chamber may be maintained at less than or about 15 Torr while contacting the silicon-containing material on the substrate with the fluorine-containing precursor. The methods may include forming plasma effluents of argon or diatomic nitrogen prior to contacting the fluorine-treated silicon-containing material with plasma effluents of argon or diatomic nitrogen. The plasma effluents of argon or diatomic nitrogen may be formed at a plasma power of less than or about 750 W. The methods may include contacting the fluorine-treated silicon-containing material with plasma effluents of argon or diatomic nitrogen forms a fluorine-doped silicon-boron-and-nitrogen-containing material. The fluorine-doped silicon-boron-and-nitrogen-containing material may be characterized by a conformality of greater than or about 90%. The fluorine-doped silicon-boron-and-nitrogen-containing material may be characterized by a thickness of less than or about 750 Å. The fluorine-doped silicon-boron-and-nitrogen-containing material may be characterized by a dielectric constant of less than or about 4.6.

Some embodiments of the present technology encompass semiconductor processing methods. The methods may include i) forming a silicon-containing material on a substrate. The methods may include ii) contacting the silicon-containing material on the substrate with a fluorine-containing precursor to form a fluorine-treated silicon-containing material. The methods may include iii) contacting the fluorine-treated silicon-containing material with plasma effluents of argon or diatomic nitrogen to form a fluorine-doped silicon-boron-and-nitrogen-containing material. The methods may include iv) repeating operations i) through iii) for at least five cycles.

In some embodiments, operations i) and ii) are performed plasma-free. The substrate may include a feature characterized by an aspect ratio of greater than or about 3:1. The fluorine-doped silicon-boron-and-nitrogen-containing material may be characterized by a conformality of greater than or about 90%. A temperature may be maintained at less than or about 550° C. during the semiconductor processing method. A pressure may be maintained at less than or about 40 Torr during the semiconductor processing method. The methods may include v) annealing the substrate and the fluorine-doped silicon-boron-and-nitrogen-containing material.

Some embodiments of the present technology encompass semiconductor processing methods. The methods may include providing one or more deposition precursors to a processing region of a semiconductor processing chamber. The one or more deposition precursors may include a silicon-containing precursor. The methods may include contacting a substrate housed in the processing region with the one or more deposition precursors. The methods may include thermally forming a layer of silicon-containing material on the substrate. The methods may include providing a fluorine-containing precursor to the processing region of the semiconductor processing chamber. The methods may include thermally contacting the layer of silicon-containing material on the substrate with the fluorine-containing precursor to form a layer of fluorine-doped silicon-containing material. The methods may include providing argon, diatomic nitrogen, or both to the processing region of the semiconductor processing chamber. The methods may include forming plasma effluents of argon, diatomic nitrogen, or both. The methods may include contacting the layer of fluorine-doped silicon-containing material with the plasma effluents of argon, diatomic nitrogen, or both to form a fluorine-doped silicon-containing material.

In some embodiments, the layer of fluorine-doped silicon-containing material is characterized by a conformality of greater than or about 90%. The plasma effluents of argon, diatomic nitrogen, or both may be formed at a plasma power of less than or about 750 W. The layer of fluorine-doped silicon-containing material may be characterized by a dielectric constant of less than or about 4.6 and a leakage current of less than or about 5.0E-08 A/cm′.

Such technology may provide numerous benefits over conventional systems and techniques. For example, performing a fluorine treatment and a plasma treatment may improve deposition characteristics. For example, performing a fluorine treatment may increase conformality of the deposited material, reduce the dielectric constant of the deposited material, and/or reduce the leakage current of the deposited material. Additionally, performing a plasma treatment may densify the material, further increasing conformality and/or reducing dielectric constant. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a top plan view of an exemplary processing system according to some embodiments of the present technology.

FIG. 2 shows a schematic cross-sectional view of an exemplary plasma system according to some embodiments of the present technology.

FIG. 3 shows operations of an exemplary method of semiconductor processing according to some embodiments of the present technology.

FIGS. 4A-4B show cross-sectional views of substrates being processed according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

In forming integrated circuits, many material layers are formed and partially or wholly removed. Some integrated circuits require the formation of spacer or liner materials to at least partially separate other materials formed on either side of the spacer. Conventional technologies may use pure thermal processes or deposition and etch looped processes to form spacer or liner materials with desirable conformality. These conventional approaches cannot achieve both low dielectric constant and high conformality simultaneously. As integrated circuits continue to shrink, material layers serving multiple purposes, such as low dielectric constant and high conformality, are increasingly desirable. Furthermore, these conventional approaches may form spacer or liner materials that do not meet leakage current or breakdown voltage requirements. Even more so, these conventional technologies may be prone to shrinkage during post-formation processing, such as an anneal, which may result in the failure to maintain desirable properties of the material.

The present technology may overcome these issues by performing fluorine treatment and/or a plasma treatment after depositing a silicon-containing material. The fluorine treatment may introduce fluorine-containing precursors to thermally treat a formed silicon-containing material, where the fluorine may dope the silicon-containing material. In doping the silicon-containing material, the fluorine may replace hydrogen bonds in the material with fluorine bonds. This replacement may smooth the surface of the silicon-containing material, increasing conformality. The plasma treatment may bombard the film with heavy inert precursors to densify the film, further increasing conformality. The fluorine treatment and/or the plasma treatment may also have a positive affect on electrical properties of the silicon-containing material, such as the dielectric constant, the leakage current, and the breakdown voltage. Conventional technologies have not been able to address all these properties of deposited films, thereby sacrificing one or more desirable properties.

Although the remaining disclosure will routinely identify specific deposition processes utilizing the disclosed technology, it will be readily understood that the systems and methods are equally applicable to other deposition chambers, as well as processes as may occur in the described chambers. Accordingly, the technology should not be considered to be so limited as for use with these specific deposition processes or chambers alone. The disclosure will discuss one possible system and chamber that may be used to perform deposition processes according to embodiments of the present technology before additional details according to embodiments of the present technology are described.

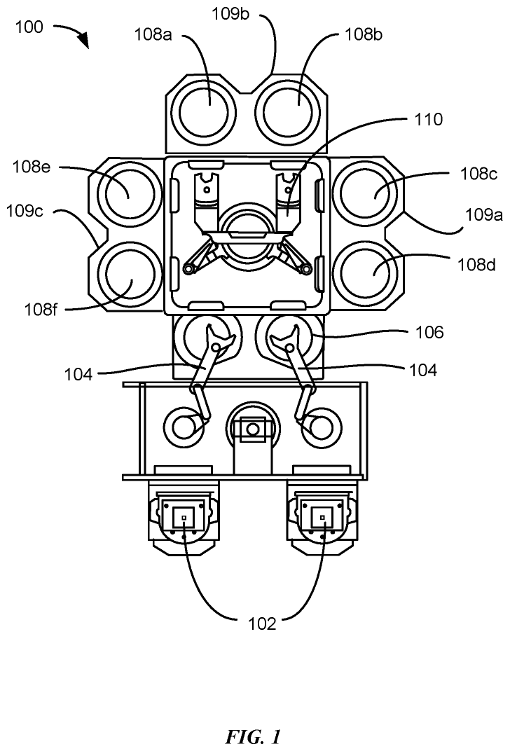

FIG. 1 shows a top plan view of one embodiment of a processing system 100 of deposition, etching, baking, and curing chambers according to embodiments. In the figure, a pair of front opening unified pods 102 supply substrates of a variety of sizes that are received by robotic arms 104 and placed into a low pressure holding area 106 before being placed into one of the substrate processing chambers 108a-f, positioned in tandem sections 109a-c. A second robotic arm 110 may be used to transport the substrate wafers from the holding area 106 to the substrate processing chambers 108a-f and back. Each substrate processing chamber 108a-f, can be outfitted to perform a number of substrate processing operations including formation of stacks of semiconductor materials described herein in addition to plasma-enhanced chemical vapor deposition, atomic layer deposition, physical vapor deposition, etch, pre-clean, degas, orientation, and other substrate processes including, annealing, ashing, etc.

The substrate processing chambers 108a-f may include one or more system components for depositing, annealing, curing and/or etching a dielectric or other film on the substrate. In one configuration, two pairs of the processing chambers, e.g., 108c-d and 108e-f, may be used to deposit dielectric material on the substrate, and the third pair of processing chambers, e.g., 108a-b, may be used to etch the deposited dielectric. In another configuration, all three pairs of chambers, e.g., 108a-f, may be configured to deposit stacks of alternating dielectric films on the substrate. Any one or more of the processes described may be carried out in chambers separated from the fabrication system shown in different embodiments. It will be appreciated that additional configurations of deposition, etching, annealing, and curing chambers for dielectric films are contemplated by system 100.

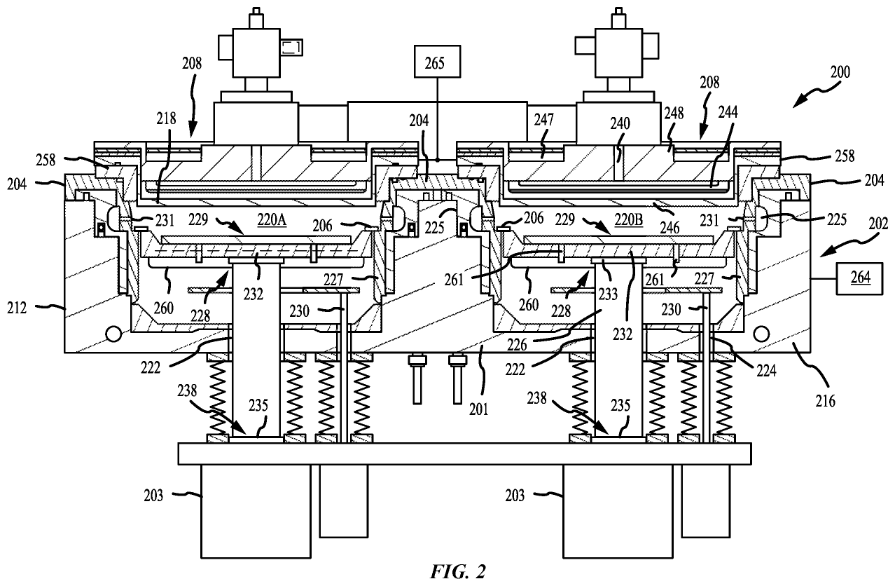

FIG. 2 shows a schematic cross-sectional view of an exemplary plasma system 200 according to some embodiments of the present technology. Plasma system 200 may illustrate a pair of processing chambers 108 that may be fitted in one or more of tandem sections 109 described above, and which may include lid stack components according to embodiments of the present technology, and as may be explained further below. The plasma system 200 generally may include a chamber body 202 having sidewalls 212, a bottom wall 216, and an interior sidewall 201 defining a pair of processing regions 220A and 220B. Each of the processing regions 220A-220B may be similarly configured, and may include identical components.

For example, processing region 220B, the components of which may also be included in processing region 220A, may include a pedestal 228 disposed in the processing region through a passage 222 formed in the bottom wall 216 in the plasma system 200. The pedestal 228 may provide a heater adapted to support a substrate 229 on an exposed surface of the pedestal, such as a body portion. The pedestal 228 may include heating elements 232, for example resistive heating elements, which may heat and control the substrate temperature at a desired process temperature. Pedestal 228 may also be heated by a remote heating element, such as a lamp assembly, or any other heating device.

The body of pedestal 228 may be coupled by a flange 233 to a stem 226. The stem 226 may electrically couple the pedestal 228 with a power outlet or power box 203. The power box 203 may include a drive system that controls the elevation and movement of the pedestal 228 within the processing region 220B. The stem 226 may also include electrical power interfaces to provide electrical power to the pedestal 228. The power box 203 may also include interfaces for electrical power and temperature indicators, such as a thermocouple interface. The stem 226 may include a base assembly 238 adapted to detachably couple with the power box 203. A circumferential ring 235 is shown above the power box 203. In some embodiments, the circumferential ring 235 may be a shoulder adapted as a mechanical stop or land configured to provide a mechanical interface between the base assembly 238 and the upper surface of the power box 203.

A rod 230 may be included through a passage 224 formed in the bottom wall 216 of the processing region 220B and may be utilized to position substrate lift pins 261 disposed through the body of pedestal 228. The substrate lift pins 261 may selectively space the substrate 229 from the pedestal to facilitate exchange of the substrate 229 with a robot utilized for transferring the substrate 229 into and out of the processing region 220B through a substrate transfer port 260.

A chamber lid 204 may be coupled with a top portion of the chamber body 202. The lid 204 may accommodate one or more precursor distribution systems 208 coupled thereto. The precursor distribution system 208 may include a precursor inlet passage 240 which may deliver reactant and cleaning precursors through a dual-channel showerhead 218 into the processing region 220B. The dual-channel showerhead 218 may include an annular base plate 248 having a blocker plate 244 disposed intermediate to a faceplate 246. A radio frequency (“RF”) source 265 may be coupled with the dual-channel showerhead 218, which may power the dual-channel showerhead 218 to facilitate generating a plasma region between the faceplate 246 of the dual-channel showerhead 218 and the pedestal 228. In some embodiments, the RF source may be coupled with other portions of the chamber body 202, such as the pedestal 228, to facilitate plasma generation. A dielectric isolator 258 may be disposed between the lid 204 and the dual-channel showerhead 218 to prevent conducting RF power to the lid 204. A shadow ring 206 may be disposed on the periphery of the pedestal 228 that engages the pedestal 228.

An optional cooling channel 247 may be formed in the annular base plate 248 of the precursor distribution system 208 to cool the annular base plate 248 during operation. A heat transfer fluid, such as water, ethylene glycol, a gas, or the like, may be circulated through the cooling channel 247 such that the base plate 248 may be maintained at a predefined temperature. A liner assembly 227 may be disposed within the processing region 220B in close proximity to the sidewalls 201, 212 of the chamber body 202 to prevent exposure of the sidewalls 201, 212 to the processing environment within the processing region 220B. The liner assembly 227 may include a circumferential pumping cavity 225, which may be coupled to a pumping system 264 configured to exhaust gases and byproducts from the processing region 220B and control the pressure within the processing region 220B. A plurality of exhaust ports 231 may be formed on the liner assembly 227. The exhaust ports 231 may be configured to allow the flow of gases from the processing region 220B to the circumferential pumping cavity 225 in a manner that promotes processing within the system 200.

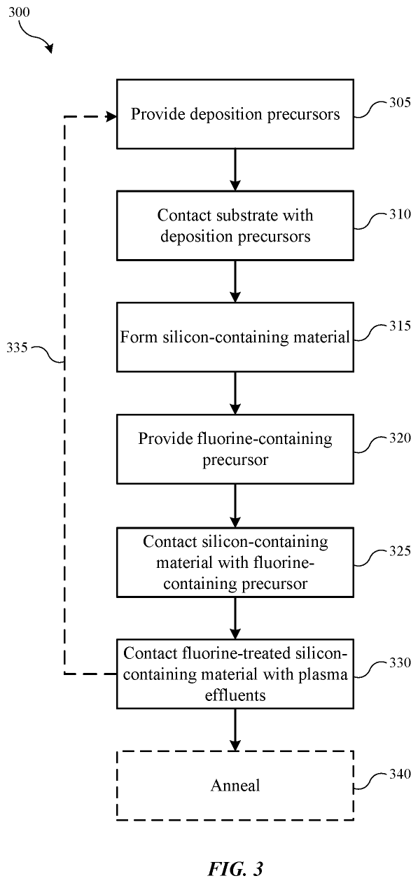

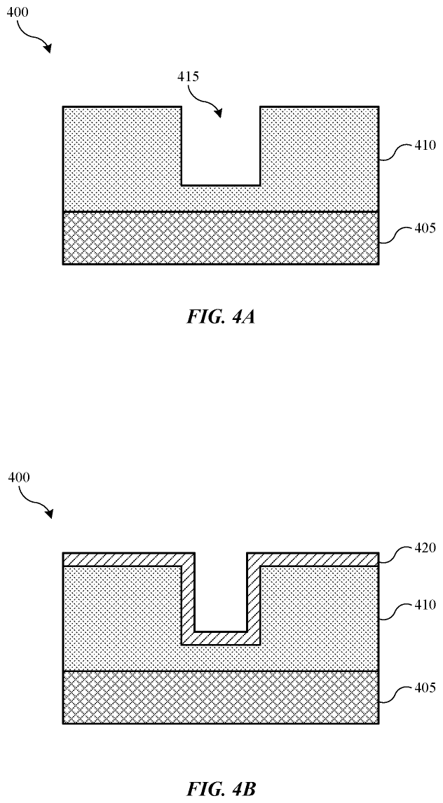

FIG. 3 shows operations of an exemplary method 300 of semiconductor processing according to some embodiments of the present technology. The method may be performed in a variety of processing chambers, including processing system 200 described above, as well as any other chamber in which plasma deposition may be performed. Method 400 may include one or more operations prior to the initiation of the method, including front end processing, polishing, cleaning, deposition, etching, or any other operations that may be performed prior to the described operations. Method 300 may include a number of optional operations, which may or may not be specifically associated with some embodiments of methods according to the present technology. For example, many of the operations are described in order to provide a broader scope of the structural formation, but are not critical to the technology, or may be performed by alternative methodology as will be discussed further below. Method 300 describes the operations shown schematically in FIGS. 4A-4B, the illustrations of which will be described in conjunction with the operations of method 300. It is to be understood that FIGS. 4A-4B illustrate only partial schematic views, and a substrate may contain any number of transistor sections having aspects as illustrated in the figures.

As illustrated in FIG. 4A, the structure 400 may include a substrate 405. The substrate 505 may be made of or contain silicon or some other semiconductor substrate material. One or more layers of material 410 may be formed over the substate 405. The one or more layers of material 410 may include or define a recess 415. The aspect ratio of the recess 415, or the ratio of hole length to hole diameter may be greater than or about 2:1, and may be greater than or about 3:1, greater than or about 4:1, greater than or about 5:1, greater than or about 6:1, greater than or bout 7:1, greater than or about 8:1, greater than or about 9:1, greater than or about 10:1, or more.

At operation 305, method 300 may include providing one or more deposition precursors into a processing chamber, which may deliver the precursors into a processing region of the chamber where a substrate 405 may be housed, such as region 220, for example. The deposition precursors may include, for example, a silicon-containing precursor, a boron-containing precursor, a nitrogen-containing precursor, or any other deposition precursors used to form silicon-containing materials.

In embodiments, the one or more deposition precursors may include a silicon-containing precursor. The silicon-containing precursor may include organosilanes, which may include silane, disilane, and other materials. Additional silicon-containing precursors may include silicon, carbon, oxygen, or nitrogen, such as trisilylamine. In embodiments, the one or more deposition precursors may include a boron-containing precursor. The boron-containing precursor may include boranes, such as borane, diborane, or other multicenter-bonded boron materials, as well as any other boron-containing materials that may be used to produce silicon-and-boron-containing materials. In some embodiments, the deposition may utilize a single deposition precursor, such as a precursor that includes silicon and boron. The precursors may or may not include delivery of additional precursors, such as carrier gases or one or more oxygen-containing precursors for depositing an oxide layer.

At operation 310, method 300 may include contacting the substrate 405 with the one or more deposition precursors. As shown in FIG. 4B, at operation 315, method 300 may include forming a silicon-containing material 420. The silicon-containing material may be formed over the one or more layers of material 410 formed over the substate 405.

Process conditions may impact the operations performed in method 300. Each of the operations of method 300 may be performed during a constant temperature in embodiments, while in some embodiments the temperature may be adjusted during different operations. In some embodiments of the present technology, method 300 may be performed at substrate, pedestal, and/or chamber temperatures less or about 550° C., which may be due to thermal budget issues, and may be performed at temperatures less than or about 525° C., less than or about 500° C., less than or about 475° C., less than or about 450° C., less than or about 425° C., less or about 400° C., less or about 375° C., less or about 350° C., less or about 325° C., less or about 300° C., or lower. The temperature may also be maintained at any temperature within these ranges, within smaller ranges encompassed by these ranges, or between any of these ranges. Forming material at increased temperatures may reduce the deposition rate and, therefore, improve conformality. Accordingly, in some embodiments, the pressure may be maintained between about 400° C. and about 500° C.

The pressure within the semiconductor processing chamber may also affect the operations performed. In embodiments, the pressure may be maintained at less than about 40 Torr. Accordingly, the pressure may be maintained at less than or about 35 Torr, less than or about 30 Torr, less than or about 25 Torr, less than or about 20 Torr, less than or about 18 Torr, less than or about 16 Torr, less than or about 14 Torr, less than or about 12 Torr, less than or about 10 Torr, less than or about 8 Torr, less than or about 6 Torr, less than or about 4 Torr, less than or about 2 Torr, less than or about 1 Torr, or less. The pressure may also be maintained at any pressure within these ranges, within smaller ranges encompassed by these ranges, or between any of these ranges. Additionally, the pressure may be adjusted during method 300 as described below. Conformality may increase with increasing pressures as the precursors may experience more scattering before reaching the substrate, thereby arriving at the substrate surface an angle that is more random for a more conformal film growth. Accordingly, in some embodiments, the pressure may be maintained between about 10 Torr and about 20 Torr.

At operation 320, method 300 may include providing a fluorine-containing precursor into a processing chamber, which may deliver the precursors into a processing region of the chamber where a substrate 405 may be housed. An exemplary fluorine-containing precursor may be nitrogen trifluoride (NF₃). Other sources of fluorine can be used in combination with nitrogen trifluoride or as a substitute for nitrogen trifluoride. In some embodiments, the fluorine-containing precursor may be or include atomic fluorine, diatomic fluorine, hydrogen fluoride, nitrogen trifluoride, carbon tetrafluoride, xenon difluoride, and various other fluorine-containing precursors used or available in semiconductor processing.

At operation 325, method 300 may include contacting the silicon-containing material 420 with the fluorine-containing precursor. The fluorine-containing precursor may dope the silicon-containing material 420 to form a silicon-doped fluorine containing material. Specifically, the fluorine-containing precursor may reorganize bonds at in the silicon-containing material, and may replace at least some Si—H bonds and B—H bonds with Si—F bonds and B—F, respectively. The less polarized fluorine bonds, compared to the previous hydrogen bonds, may lower the dielectric constant of the silicon-containing material 420. The fluorine bonds may reduce the leakage current of the silicon-containing material 420. Furthermore, the contacting of the silicon-containing material 420 with the fluorine-containing precursor may form Si—F bonds from dangling silicon bonds on the surface of the silicon-containing material 420. Due to the formation of Si—F bonds from dangling silicon bonds, as well as the increased polarization stability of fluorine, the surface of the silicon-containing material 420 may be stabilized, thereby alleviating distorted portions on the surface. By alleviating distorted portions on the surface of the silicon-containing material 420, conformality may be increased. After being contacted with the fluorine-containing precursor, the silicon-containing material 420 may be characterized by a fluorine concentration of less than or about 30 at. %, and may be characterized by a fluorine-concentration of less than or about 28 at. %, less than or about 26 at. %, less than or about 24 at. %, less than or about 22 at. %, less than or about 20 at. %, less than or about 18 at. %, less than or about 16 at. %, less than or about 14 at. %, less than or about 12 at. %, less than or about 10 at. %, or less.

In embodiments, method 300 may include reducing a pressure during operations 320 and 325. For example, the pressure may be reduced to less than or about 15 Torr, less than or about 14 Torr, less than or about 13 Torr, less than or about 12 Torr, less than or about 11 Torr, less than or about 10 Torr, less than or about 9 Torr, less than or about 8 Torr, less than or about 7 Torr, less than or about 6 Torr, less than or about 5 Torr, less than or about 4 Torr, less than or about 3 Torr, less than or about 2 Torr, less than or about 1 Torr, or less. At lower pressures, compared to operations 305-315, a residence time of the fluorine-containing precursor may reduce. At lower pressures, the mean free path may increase, allowing for increased interaction between the fluorine-containing precursor and the silicon-containing material 420.

The fluorine treatment at operations 320 and 325 may continue for a period of time sufficient for the fluorine-containing precursor to interact with the silicon-containing material 420. For example, the fluorine treatment at operations 320 and 325 may continue for a period of time of between about 2 seconds and about 60 seconds. However, it is contemplated that operations 320 and 325 may continue for a period of time of less than about 2 seconds and/or greater than or about 60 seconds depending on a variety of conditions, such as temperature, pressure, a flow rate of the fluorine-containing precursor, as well as the properties and characteristics of the silicon-containing material 420.

In embodiments, the method 300 may include halting a flow of the one or more deposition precursors prior to providing the fluorine-containing precursor at operation 320. By halting the flow of the one or more deposition precursors, the deposition of material may be reduced or halted, allowing the fluorine-containing precursor to dope the formed silicon-containing material 420. However, it is contemplated that a flow of the one or more deposition precursors may alternatively be reduced and/or maintained during operation 320.

At operation 330, method 300 may include contacting the fluorine-treated silicon-containing material with plasma effluents. It is noted that prior to operation 330, the semiconductor processing chamber may be maintained plasma-free, such as at any or all of operations 305-325. The method 300 may include providing one or more plasma treatment precursors into the processing chamber, which may deliver the precursors into a processing region of the chamber where the substrate 405 may be housed. The plasma treatment precursors may include a nitrogen-containing precursor, such as diatomic nitrogen, which may impart nitrogen into the silicon-containing material 420. After being treated with the fluorine-containing precursor, the plasma treatment at operation 330 may form a fluorine-doped silicon-and-nitrogen-containing material, such as a fluorine-doped silicon-boron-and-nitrogen-containing material. The plasma treatment precursors may also include one or more inert species, such as argon, neon, xenon, or hydrogen.

The plasma effluents of the one or more plasma treatment precursors may be generated at a plasma power of less than or about 750 W. At plasma powers greater than 750 W, a potential for arcing may increase which may be detrimental to the plasma treatment and to the formation of the fluorine-doped silicon-containing material. Accordingly, the plasma effluents of the one or more plasma treatment precursors may be generated at a plasma power of less than or about 700 W, and may be generated at less than or about 650 W, less than or about 600 W, less than or about 550 W, less than or about 500 W, less than or about 450 W, less than or about 400 W, less than or about 350 W, less than or about 300 W, less than or about 250 W, less than or about 200 W, less than or about 150 W, or less.

The plasma treatment at operation 330 may impart material into the silicon-containing material 420, such as through plasma effluents of the nitrogen-containing precursor. In addition, plasma effluents of the inert precursor may bombard the film and densify the silicon-containing material 420. In densifying the silicon-containing material 420, conformality may be further increased. The use of a heavy inert precursor, such as argon, may impact the film to densify the silicon-containing material 420. The plasma treatment at operation 330 may be performed at the reduced pressures of operations 320 and 325, which may increase the plasma density and helping to more uniformly densify the film, again leading to increased conformality of the silicon-containing material 420.

The plasma treatment at operation 330 may continue for a period of time sufficient for the plasma to interact with the silicon-containing material 420. For example, the plasma treatment at operation 330 may continue for a period of time of between about 2 seconds and about 60 seconds. However, it is contemplated that operation 330 may continue for a period of time of less than about 2 seconds and/or greater than or about 60 seconds depending on a variety of conditions, such as temperature, pressure, a flow rate of the plasma treatment precursors, as well as the properties and characteristics of the silicon-containing material 420.

After the plasma treatment at operation 330, the fluorine-doped silicon-containing material 420 may be characterized by a thickness of less than or about 40 Å. If the silicon-containing material 420 is formed to a thickness greater than 40 Å, the fluorine treatment at operations 320 and 325 and the plasma treatment at operation 330 may not be as effective. Accordingly, the silicon-containing material 420 may be formed to a thickness less than or about 35 Å, less than or about 30 Å, less than or about 25 Å, less than or about 20 Å, less than or about 15 Å, less than or about 10 Å, less than or about 5 Å, or less.

As shown in FIG. 3, method 300 may include repeating operations 300-330 for a number of cycles at operation 335. By repeating operations 300-330, a silicon-containing material 420 with increased thickness may be formed. In embodiments, the operations of method 300 may be repeated for at least two cycles, at least three cycles, at least four cycles, at least five cycles, at least ten cycles, at least fifteen cycles, at least twenty cycles, at least thirty cycles, at least forty cycles, at least fifty cycles, or more. Accordingly, after repeating the operations for a number of cycles, the silicon-containing material may be characterized by a thickness of up to about 750 Å or 500 Å, such as greater than or about 100 Å, greater than or about 125 Å, greater than or about 150 Å, greater than or about 175 Å, greater than or about 200 Å, greater than or about 250 Å, greater than or about 300 Å, greater than or about 350 Å, greater than or about 400 Å, greater than or about 450 Å, greater than or about 500 Å, greater than or about 550 Å, greater than or about 600 Å, greater than or about 650 Å, greater than or about 700 Å, or more.

As previously discussed, the present technology may form silicon-containing materials characterized by reduced dielectric constants and increased electrical performance. For example, the silicon-containing materials formed according to the present technology may be characterized by a conformality of greater than or about 90%, such as greater than or about 91%, greater than or about 92%, greater than or about 93%, greater than or about 94%, greater than or about 95%, or more. Additionally, the silicon-containing materials formed according to the present technology may be characterized by a dielectric constant of less than or about 4.6, such as less than or about 4.5, less than or about 4.5, less than or about 4.4, less than or about 4.3, less than or about 4.2, less than or about 4.1, less than or about 4.0, less than or about 3.9, or less. The silicon-containing materials formed according to the present technology may be characterized by a leakage current of less than or about 5.0E-08 Å/cm², such as less than or about 4.8E-08 Å/cm², less than or about 4.6E-08 Å/cm², less than or about 4.4E-08 Å/cm², less than or about 4.2E-08 Å/cm², less than or about 4.0E-08 Å/cm², less than or about 3.9E-08 Å/cm², less than or about 3.8E-08 Å/cm², or less. Conventional technologies may not be able to produce a silicon-containing film characterized by a conformality of greater than or about 90%, a dielectric constant of less than or about 4.6, and/or a leakage current of less than or about 5.0E-08 Å/cm². The fluorine treatment and plasma treatment of the present technology may sufficiently modify the formed silicon-containing materials to tune the properties of the film as described.

In embodiments, at optional operation 340, an anneal or other rapid thermal process may be performed after the silicon-containing material 420 is formed to a desired thickness. The anneal or other process may not substantially alter the characteristics of the silicon-containing material, indicating the thermal stability of the silicon-containing material 420.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a silicon-containing precursor” includes a plurality of such silicon-containing precursors, and reference to “the layer of material” includes reference to one or more layers of material and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A semiconductor processing method comprising:
providing one or more deposition precursors to a processing region of a semiconductor processing chamber;
contacting a substrate housed in the processing region with the one or more deposition precursors;
forming a silicon-containing material on the substrate;
providing a fluorine-containing precursor to the processing region of the semiconductor processing chamber;
contacting the silicon-containing material on the substrate with the fluorine-containing precursor to form a fluorine-treated silicon-containing material; and
contacting the fluorine-treated silicon-containing material with plasma effluents of argon or diatomic nitrogen.

2. The semiconductor processing method of claim 1, wherein the one or more deposition precursors comprise a silicon-containing precursor and a boron-containing precursor.

3. The semiconductor processing method of claim 1, wherein a temperature within the semiconductor processing chamber is maintained at less than or about 550° C. during the semiconductor processing method.

4. The semiconductor processing method of claim 1, wherein the substrate comprises a feature characterized by an aspect ratio of greater than or about 3:1.

5. The semiconductor processing method of claim 1, further comprising:
subsequent to forming the silicon-containing material on the substrate, halting a flow of the one or more deposition precursors; and
reducing a pressure within the semiconductor processing chamber prior to providing the fluorine-containing precursor to the processing region of the semiconductor processing chamber.

6. The semiconductor processing method of claim 5, wherein the pressure within the semiconductor processing chamber is maintained at less than or about 15 Torr while contacting the silicon-containing material on the substrate with the fluorine-containing precursor.

7. The semiconductor processing method of claim 1, further comprising:
forming plasma effluents of argon or diatomic nitrogen prior to contacting the fluorine-treated silicon-containing material with plasma effluents of argon or diatomic nitrogen, wherein the plasma effluents of argon or diatomic nitrogen are formed at a plasma power of less than or about 750 W.

8. The semiconductor processing method of claim 1, wherein:
contacting the fluorine-treated silicon-containing material with plasma effluents of argon or diatomic nitrogen forms a fluorine-doped silicon-boron-and-nitrogen-containing material; and
the fluorine-doped silicon-boron-and-nitrogen-containing material is characterized by a conformality of greater than or about 90%.

9. The semiconductor processing method of claim 8, wherein the fluorine-doped silicon-boron-and-nitrogen-containing material is characterized by a thickness of less than or about 750 Å.

10. The semiconductor processing method of claim 8, wherein the fluorine-doped silicon-boron-and-nitrogen-containing material is characterized by a dielectric constant of less than or about 4.6.

11. A semiconductor processing method comprising:
i) forming a silicon-containing material on a substrate;
ii) contacting the silicon-containing material on the substrate with a fluorine-containing precursor to form a fluorine-treated silicon-containing material;
iii) contacting the fluorine-treated silicon-containing material with plasma effluents of argon or diatomic nitrogen to form a fluorine-doped silicon-boron-and-nitrogen-containing material; and
iv) repeating operations i) through iii) for at least five cycles.

12. The semiconductor processing method of claim 11, wherein operations i) and ii) are performed plasma-free.

13. The semiconductor processing method of claim 11, wherein the substrate comprises a feature characterized by an aspect ratio of greater than or about 3:1.

14. The semiconductor processing method of claim 11, wherein the fluorine-doped silicon-boron-and-nitrogen-containing material is characterized by a conformality of greater than or about 90%.

15. The semiconductor processing method of claim 11, wherein:
a temperature is maintained at less than or about 550° C. during the semiconductor processing method; and
a pressure is maintained at less than or about 40 Torr during the semiconductor processing method.

16. The semiconductor processing method of claim 11, further comprising
v) annealing the substrate and the fluorine-doped silicon-boron-and-nitrogen-containing material.

17. A semiconductor processing method comprising:
providing one or more deposition precursors to a processing region of a semiconductor processing chamber, wherein the one or more deposition precursors comprise a silicon-containing precursor;
contacting a substrate housed in the processing region with the one or more deposition precursors;
thermally forming a layer of silicon-containing material on the substrate;
providing a fluorine-containing precursor to the processing region of the semiconductor processing chamber;
thermally contacting the layer of silicon-containing material on the substrate with the fluorine-containing precursor to form a layer of fluorine-doped silicon-containing material;
providing argon, diatomic nitrogen, or both to the processing region of the semiconductor processing chamber;
forming plasma effluents of argon, diatomic nitrogen, or both; and
contacting the layer of fluorine-doped silicon-containing material with the plasma effluents of argon, diatomic nitrogen, or both to form a fluorine-doped silicon-containing material.

18. The semiconductor processing method of claim 17, wherein the layer of fluorine-doped silicon-containing material is characterized by a conformality of greater than or about 90%.

19. The semiconductor processing method of claim 17, wherein the plasma effluents of argon, diatomic nitrogen, or both are formed at a plasma power of less than or about 750 W.

20. The semiconductor processing method of claim 17, wherein the layer of fluorine-doped silicon-containing material is characterized by:
a dielectric constant of less than or about 4.6; and
a leakage current of less than or about 5.0E-08 Å/cm².
